(19) United States
(12) Patent Application Publication
(10) Pub. No.: US 2013/0075545 A1
(43) Pub. Date: Mar. 28, 2013

(54) SUPPORTING FRAMEWORK FOR A PHOTOVOLTAIC MODULE AND TRACKING DEVICE FOR A PHOTOVOLTAIC SYSTEM

(71) Applicant: HANS-PETER FISCHER, WENDELSTEIN (DE)

(72) Inventor: HANS-PETER FISCHER, WENDELSTEIN (DE)

(21) Appl. No.: 13/684,701

(22) Filed: Nov. 26, 2012

Related U.S. Application Data
(63) Continuation of application No. PCT/EP2010/003164, filed on May 25, 2010.
Application No. PCT/EP2010/003164 is a continuation of application No. PCT/EP2010/006063, filed on Oct. 5, 2010.

(51) Int. Cl. H01L 31/042

(52) U.S. Cl. CPC H01L 31/0422
USPC 248/122.1

(57) ABSTRACT

In order to allow reliable and safe vertical tracking with a simple design at the same time for a photovoltaic installation having a multiplicity of photovoltaic modules which are arranged on supporting frameworks. Each of the frameworks has a driver element which, in particular, is cylindrical and has a common drive device that loop or wraps around it in the installed state. In order to prevent slippage between the drive device and the driver element, there is provided a friction braking device which, in a particular embodiment, is formed by a guide slot in the driver element.

### CROSS-REFERENCE TO RELATED APPLICATION

This application is a continuation application, under 35 U.S.C. §120, of copending international patent application No. PCT/EP2010/006063, filed Oct. 5, 2010, and of international patent application No. PCT/EP2010/003164, filed May 25, 2010, which both designated the United States; the prior applications are herewith incorporated by reference in their entirety.

### BACKGROUND OF THE INVENTION

### Field of the Invention

The invention relates to a supporting framework for a photovoltaic module, having the features of the preamble of patent claim 1, and also to a tracking device for a photovoltaic system having a plurality of such supporting frameworks.

European patent EP 1 710 651 B1 discloses a biaxial tracking device, in which both vertical and horizontal tracking is provided.

In photovoltaic systems, the achievable energy yield depends on the incidence angle of the Sun in relation to the photovoltaic module, and so, in order to increase the energy yield, it is expedient to use devices which make the photovoltaic modules of the system track the position of the Sun, which changes depending on the time of year or day. In this case, mention should first of all be made of vertical tracking, in which the photovoltaic module is made to track the Sun's path by rotation of the supporting structure that carries the module about an axis which is substantially vertical with respect to the surface of the Earth. In addition, in the case of biaxial tracking, horizontal tracking is also possible in that the photovoltaic module is pivoted or inclined in a horizontal axis, so that ideally a right angle with respect to the Sun is ensured.

In the case of the tracking device described in EP 1 710 651 B1, a plurality of supporting frameworks for a respective photovoltaic module are provided via a common drive means, in particular a cable, for transmitting an actuating movement of a drive motor assigned jointly to the supporting frameworks. The cable is in this case guided in each case around a driver element, which is in the form of an approximately cylindrical drum, and wraps around the latter. The advantage of this drive arrangement having the one common motor for a large number of supporting frameworks is that, even in the case of a large number of installed photovoltaic modules, only one or a few motors are required.

### SUMMARY OF THE INVENTION

It is accordingly an object of the invention to provide a supporting frame and tracking device which overcome various disadvantages of the heretofore-known devices and methods of this general type and which provides for a supporting framework and also a tracking device in which reliable transmission of the actuating movement is ensured.

With the foregoing and other objects in view there is provided, in accordance with the invention, a supporting framework for a photovoltaic module for tracking a movement of the sun, the supporting framework comprising:

a supporting column and a driver element surrounding said supporting column and connected thereto so as to rotate therewith;

a drive device for transmitting a drive force to said driver element disposed to wrap around said driver element in an assembled state;

a friction braking device disposed to avoid slip between said driver element and said drive device;

said driver element having a lateral surface formed with at least one guide slot extending in a circumferential direction, with said drive device resting in said guide slot in the assembled state such that said drive device extends in a straight line along a length of said guide slot and rests against edges at an inlet-side end and an outlet-side end of said guide slot.

In other words, the objects of the invention are achieved with a supporting framework, or mounting rack, which in the assembled state is part of a tracking device for a photovoltaic system that includes a large number of photovoltaic modules, which are made to track the Sun preferably exclusively vertically. The supporting framework is designed for automatic vertical tracking of the photovoltaic module mounted on the supporting framework in operation. It comprises a supporting column and also a, preferably cylindrical, driver element which surrounds the supporting column and is connected thereto so as to rotate therewith. An in particular flexible drive means for transmitting a drive force wraps around the driver element in the assembled state. In order to ensure a connection between the drive means and the driver element that is as slip-free as possible, there is provided a friction braking device which acts between the drive means and the driver element. In the assembled state, a plurality of supporting frameworks are connected via the common drive means for vertical tracking.

Specifically, with regard to simple installation, the drive means is usually connected only loosely, that is to say without a firm and form-fitting connection, to the driver element. When use is made of a cable, the latter is guided around the driver element. Preferably, the cable wraps around the driver element in this case in the manner of a loop, i.e. the cable is guided at least once or a plurality of times around the driver element. The drive force is transmitted in this case via the associated friction between the drive means and the driver element, without a form fit being formed. Depending on the size of the photovoltaic system, preferably a plurality of 10 up to for example 30 or 40 supporting frameworks are connected together via a common drive motor and via the common drive means. Tests have shown that in this case the problem can occur that, on account of slip between the driver element and the drive means, the different supporting frameworks undergo different vertical tracking, i.e. in an array having a large number of such supporting frameworks there is the risk that the rotational orientations of the latter will be different, and this should be avoided with regard to a solar yield which is as efficient as possible.

In order to avoid this and at the same to maintain the installation which is as simple as possible by way of simple wrapping of the driver element, there is provided the friction braking device, which increases the friction that acts between the driver element and the drive means, so that slip between the two elements is avoided.

Expediently, the driver element has to this end a lateral surface which has structuring as a friction braking device. For example, the lateral surface is provided to this end with elevations and depressions, i.e. for example radially protruding ribs, in order to increase the friction.

In a preferred embodiment, the lateral surface has at least one guide slot which extends along a section in the circumferential direction. In the assembled state, the driver element is accommodated in this guide slot. On account of the incorporation of the guide slot, the cable therefore no longer rests smoothly against the lateral surface in this region, but rather extends in a straight line along the length of the guide slot. At the inlet-side and outlet-side ends of the guide slot, the cable rests against edges, such that as a result the friction is markedly increased and slip is avoided. The guide slot extends for example through a rotation angle of more than 20° and preferably more than 30° around the circumference of the driver element. The guide slot therefore covers a comparatively large circumferential angle, and this has a positive effect on the desired high frictional force between the cable and the guide slot edges.

In order to ensure reliable guidance of the drive means about the driver element and in particular to ensure that the drive means extends through the guide slot, in an expedient development there is provided a guide element for guiding the drive means. This is formed in particular by elements protruding radially from the lateral surface, for example guide ribs, protuberances or the like. The guide element thus prevents the driver element from slipping along the lateral surface in the vertical direction.

This is advantageous in particular when photovoltaic systems are installed in open country with uneven ground, with the individual supporting frameworks not being arranged at an identical horizontal height. The drive means can therefore under certain circumstances extend at an angle to the vertical axis and be guided to the driver element.

Expediently, the guide element has in this case a guide region that converges toward the friction braking device, such that the drive means is guided to the friction braking device, in particular the guide slot, even in the event of an inclined course. This is achieved for example by two opposite guide ribs which run toward one another or are formed in a wedge-shaped manner and protrude radially from the lateral surface.

Biaxial tracking devices, in which, in addition to vertical tracking about a vertical axis, horizontal tracking about a horizontal axis is also provided, generally require high structural outlay and/or separate servomotors for the two tracking movements. In the case of the forced mechanical coupling, to be gathered from the above-mentioned EP 1 170 651 B1, between the vertical and horizontal tracking, a high frictional force has to be overcome by the drive. In order then to achieve a cost-effective structure both of the supporting framework and with regard to the possibility of using lower-powered motors, it is provided in an expedient embodiment that the supporting framework is formed exclusively for automatic vertical tracking. Automatic horizontal tracking, in which the inclination angle takes account of the position of the Sun during the day by way of a varying horizontal inclination, is not provided.

In order additionally to ensure at the same time a solar yield which is as high as possible depending on the installation location of the photovoltaic system, it is additionally provided that a fixing apparatus is provided for manually setting a horizontal inclination angle. The supporting framework has to this end a supporting frame, on which the respective photovoltaic module rests in the assembled state. This supporting frame is mounted in a movable manner about a horizontal pivot axis. At the same time, a defined horizontal inclination angle is settable manually via the fixing apparatus. Thus, for example, depending on the installation location (degree of latitude), a horizontal inclination angle that is as optimal as possible is set, preferably once when the system is installed or set into operation.

Expediently, the fixing apparatus in this case comprises a plurality of discrete locking settings for setting defined horizontal inclination angles. This is achieved in particular in that the fixing apparatus comprises a linkage which is arranged between the supporting column and the supporting frame and which has a variable fastening end, which is lockable or fastenable preferably to the supporting column in different positions, in order to be able to set the different inclination angles. In particular, to this end a perforated plate is arranged on the supporting column.

Preferably, the supporting framework comprises an adjusting device, via which the rotational orientations of various part regions of the supporting column are adjustable with respect to one another, that is to say are fixable to one another in a reversible manner with respect to one another. This adjusting device serves to simplify assembly or to carry out simple readjustment during operation. In the case of a photovoltaic system having a large number of supporting frames which are connected together and the vertical tracking of which takes place via a common drive motor, there is the problem that, on account of tolerances and play in the drive train, the individual photovoltaic modules assume different azimuth angles, i.e. different rotation angles about the vertical axis, after the installation of the common drive means. On account of the division of the supporting structure into two part regions, which are rotationally adjustable with respect to one another, the advantage is achieved that, after installation of the system, when the vertical orientation between different supporting frameworks is not entirely synchronous on account of such play and tolerance effects, the vertical rotational position of individual supporting frameworks is easily settable without the supporting frame as a whole having to be rotated with respect to an anchoring element.

The two part regions of the supporting column are connected together at the dividing point preferably via flanges. At least one of the flanges has a slot guide, which is preferably curved along a circular path, for a fastening element such as a screw. The flanges ensure easy assemblability and high mechanical stability. Usually, it is provided that the drive for vertical tracking acts on one of the two part regions, in particular the lower part region.

According to a preferred development, the flange of the lower part region of the supporting column forms an upper termination for the driver element, i.e. the dividing point is arranged at the upper end of the driver element. In the case of the hollow cylindrical configuration of the driver element, this flange preferably forms a cover, such that a closed structural unit is formed. A bearing region of the supporting column on the foot plate is better protected as a result.

The object is furthermore achieved according to the invention by a tracking device for a photovoltaic system, in which a plurality of such supporting frameworks are connected together via a common drive means, in particular a cable. The drive means is in this case driven via a common drive in order to exert an actuating movement for the supporting frameworks for vertical tracking. In this case, the drive means is guided frictionally about the driver elements, and preferably the drive means wraps around said driver elements completely or multiply.

Other features which are considered as characteristic for the invention are set forth in the appended claims.

Although the invention is illustrated and described herein as embodied in a supporting framework for a photovoltaic module and tracking device for a photovoltaic system, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 shows a perspective illustration of a supporting framework to which a photovoltaic module is fastened;

FIG. 2 shows a side illustration of the supporting framework according to FIG. 1;

FIG. 3 shows a roughly simplified illustration of a tracking device having a plurality of supporting frameworks connected via a common drive means and driven by a common drive motor;

FIG. 4 shows a perspective enlarged illustration of the ground-side region of the supporting framework having a cylindrical driver element arranged around a supporting column;

FIG. 5 shows a side illustration of the elements according to FIG. 3;

FIG. 6 shows a simplified side illustration of a driver having a guide slot and guide elements; and

FIG. 7 shows a sectional illustration in the region of the driver to illustrate the adjusting device.

### DESCRIPTION OF THE INVENTION

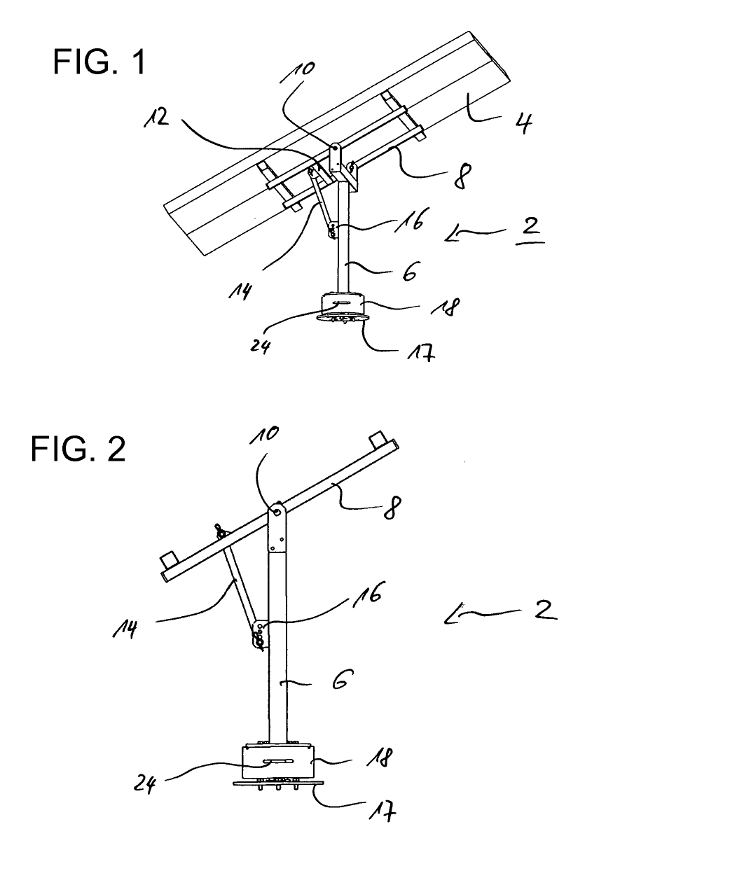

Referring now to the figures of the drawing, where identical or functionally equivalent parts and elements are identified with the same reference signs, and first, particularly, to FIG. 1 thereof, there is shown a supporting framework 2 to which a photovoltaic module 4 is attached. The photovoltaic module 4 can in this case be composed again of individual part modules that are electrically connected together.

The supporting framework 2—as is illustrated also in FIG. 2—comprises a vertically extending supporting column 6 or mast 6 which carries at its upper end a supporting frame 8 to which the photovoltaic module 4 is fastened. The inclination of the supporting frame 8 is in this case adjustable about a horizontal pivot axis 10. Arranged in a manner spaced apart from the pivot axis 10 is a strut 12 of the supporting frame 8, a linkage 14 consisting of a bar being fastened to said strut 12 in a rotationally movable manner. The linkage 14 is fastened at its lower end to the supporting columns 6. For this purpose, a perforated plate 16, i.e., a plate with several bores, is fastened to the supporting column 6 in the exemplary embodiment. The linkage 14 is fastenable in different vertical positions in this perforated plate 16 with the aid of a fastening element. The linkage 14 with the perforated plate 16 therefore forms a fixing apparatus for manually setting a horizontal inclination angle of the supporting frame 8.

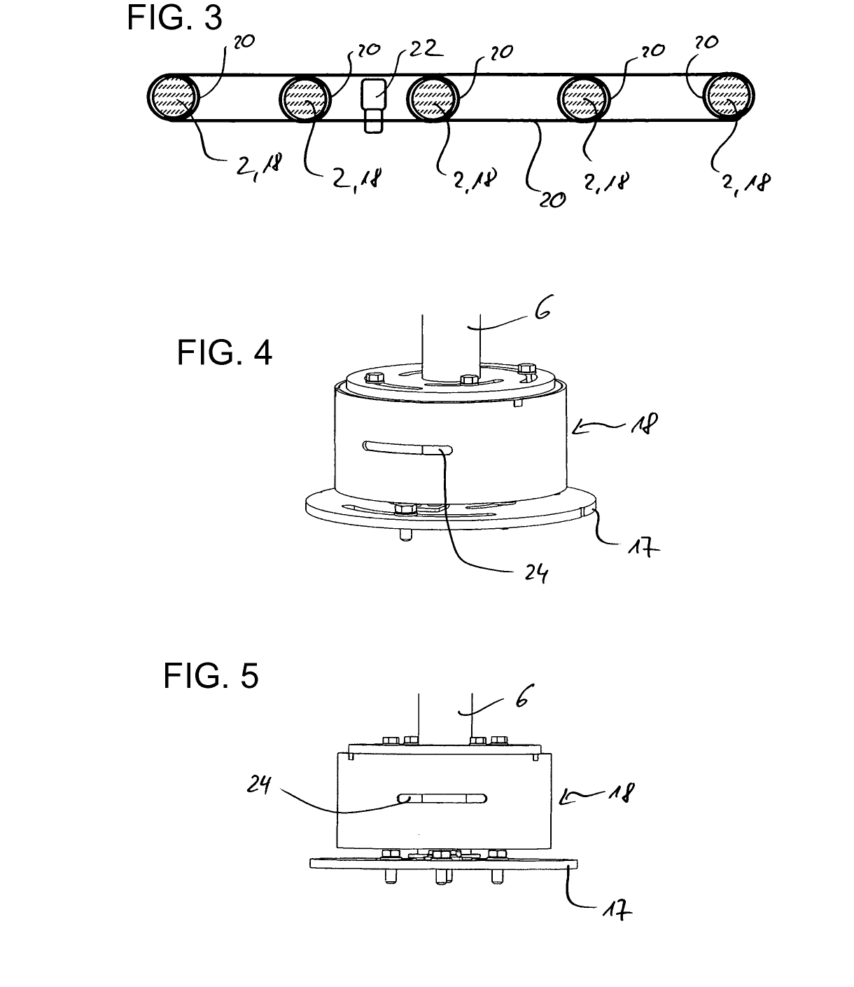

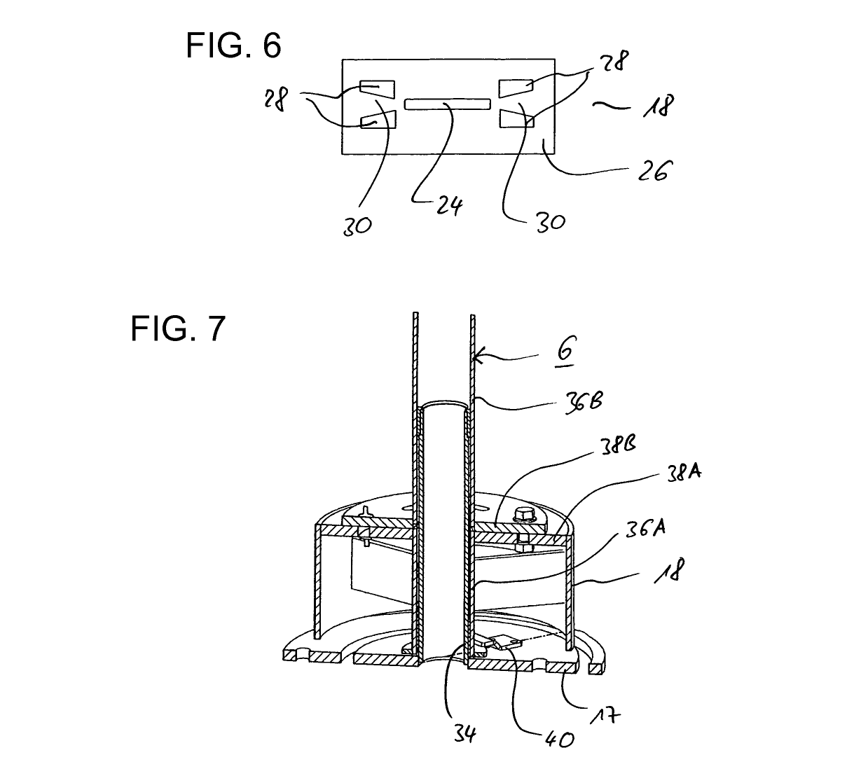

The supporting framework 2 has at its lower, ground-side end a fastening foot 17, by way of which it is intended to be anchored on the ground. To this end, in the exemplary embodiment, there is provided a flange-like plate, which can be anchored in the ground via screws. In the exemplary embodiment, immediately above the fastening foot 17 there is provided a driver element 18. Via the latter, an actuating movement, namely a rotary movement about the vertical axis of the supporting column 6, is exerted on the supporting column 6 with the aid of a drive device 20, referred to as drive means 20 (cf. FIG. 3). As a result, vertical tracking of the photovoltaic module 4, that is to say tracking in the east-west direction, is made possible. As a result of the arrangement in the immediate vicinity of the ground, the tilting moments (with respect to the vertical) that are exerted on the supporting framework 2 via the drive means 20 are kept small.

In a photovoltaic system, usually a large number of such supporting frameworks 2 having photovoltaic modules 4 are arranged in one or more rows. By way of example, and in a roughly simplified manner, FIG. 3 illustrates a single-row arrangement with a total of five supporting frameworks 2 which are symbolized by the driver element 18. As can be seen therefrom, the individual supporting frameworks 2 are connected together via the common drive means 20, in particular a cable (wire cable), and, in order to perform vertical tracking, the rotary movement is transmitted synchronously to all of the driver elements 18 via the drive means 20. In this case, the drive means 20 is wrapped around each of the driver elements 18, i.e. it runs around each driver element 18 fully at least once. Furthermore, there is arranged a common drive 22, in particular an electric motor, via which the actuating force is transmitted to the drive means. The supporting framework 2 forms, together with the drive means 20 and the drive 22, a tracking device for vertical tracking of the individual photovoltaic modules. Tracking is controlled in a manner dependent on the time of day.

In order to ensure a synchronous rotary adjustment of the individual supporting frameworks 2, there is provided a friction braking device, which is configured in the exemplary embodiment as a circumferentially extending guide slot 24 which has been introduced into a lateral surface 26, i.e., a jacket surface 26, of the driver element 18 in the form of a hollow cylinder. The configuration of the driver element 18 with the guide slot 24 can be seen best in FIGS. 3 to 5. The guide slot 24 has for example a width of 5 to 10 mm and extends preferably over a rotation angle for example in the range of 20° to 60° in the circumferential direction.

By way of this friction braking device configured in such a way, the friction force acting between the drive means 20 (cable) and the driver element 18 is increased considerably compared with a configuration without a guide slot 24, and so slip between the drive means 20 and the driver element 18 is avoided. When the cable is tensioned upon setting into operation, it rests against the peripheral edges (as seen in the circumferential direction) of the guide slot 24, such that these edges form a friction brake that acts in both directions with only little structural outlay. As a result, synchronous vertical tracking of all of the supporting frameworks 2 is ensured.

FIG. 5 shows a variant embodiment, in which, in addition to the guide slot 24, further guide elements 28 are arranged on the lateral surface 26. In the exemplary embodiment, these are arranged in the circumferential direction on both sides with respect to the guide slot 24. Each guide element 28 is in this case formed by two opposing guide ribs, which protrude radially from the lateral surface 26 and define a guide region 30 between one another. In the exemplary embodiment, this guide region 30 converges towards the guide slot. By way of these guide elements 28, reliable and secure guidance of the drive means 20 in the desired nominal position is achieved even in the case of installation in open country, in which the various supporting frameworks 2 are fastened at different heights. Slipping in the vertical direction is avoided.

As can be seen from FIG. 7, the supporting column 6 is arranged, together with the driver element 18, in a rotatable manner on the fastening foot 17. To this end, in the exemplary embodiment, the fastening foot 17 has a vertically extending supporting tube 34 over which the hollow-cylindrically formed supporting column 6 is fitted. The supporting column 6 itself is in this case subdivided into two part regions 36A, 36B which are connected together via a flange connection. To this end, a fastening flange 38A, B is arranged at the end of each of the part regions 36A, B, said fastening flanges being in the form of radially protruding and in particular circularly annular plates in the exemplary embodiment. The two fastening flanges 38A, B and thus the two part regions 36A, B are fastenable to one another in different rotational positions. To this end, in particular a slot guide and fastening elements are provided. As a result, an adjusting device for the rotational adjustment of the two part regions 36A, B with respect to one another is formed overall. This adjusting device serves to simplify assembly, in order in the event of setting into operation, after construction and wrapping of the individual driver elements 18 with the drive means 20, to be able to orient the individual photovoltaic modules 4 exactly in the same east-west angular position. As a result, in the event of setting into operation, a synchronous orientation of all of the photovoltaic modules 4 is made possible in an easy manner. Via the dividing point, a decoupling possibility between the drive train and the upper part region is generally defined.

As can be gathered from FIG. 7, the driver element 18 is formed in the manner of a hollow cylinder which is connected to the lower part region 36A in a rotationally fixed manner via struts. In the exemplary embodiment, the flange 38A of the lower part region 36A forms at the same time an upper cover for the hollow-cylindrical driver element 18. Overall, this creates a largely closed interior cavity, in which in particular the bearing point of the supporting column 6 rests in a protected manner.

In order to avoid running difficulties, sliding elements in the form of bearing sleeves are provided in the exemplary embodiment. These are arranged in each case in the lower and upper region of the supporting tube 34. Preferably, both bearing sleeves have a kind of annular flange. The supporting column 6 is supported by way of its lower end, at which it likewise forms an annular flange, on this annular flange of the bearing sleeve, such that relatively planar contact is formed. The bearing sleeves consist for example of an abrasion-resistant plastics material or of a suitable metal.

Furthermore, a storm protection means 40 is provided for the supporting column 6, such that the supporting column is secured against lifting axially off the fastening foot 17 while at the same time being rotatable. To this end, in the exemplary embodiment, a form fit which acts in the axial direction is formed between the fastening foot 17 and the supporting column 6, in particular the ground-side flange thereof. The storm protection means 40 is in this case formed in a simple manner by way of a curved lug, one end of which is fastened to the fastening foot 17 and the other end of which protrudes over the flange, in particular with a small axial spacing.

The supporting framework 2 described here and also the tracking device described with respect to FIG. 3 are distinguished overall by a simple structure and high operational reliability. The simple structure is also decisively characterized in particular by the supporting framework 2 formed only for uniaxial, vertical automatic tracking. In this case, it is furthermore particularly advantageous that, via the fixing apparatus, manual setting of the horizontal inclination angle can be carried out, in order to ensure as high a solar yield as possible in spite of the simplified structure. For the simple and cost-effective structure, the configuration with the driver element 18 and the common drive 22 and also the common drive means 20 for a large number of supporting frameworks 2 is furthermore of particular significance. By way of the friction braking device, reliable operation with synchronous vertical tracking is ensured. With regard to the simple installation, the adjusting device, which allows exact synchronous adjustment of the individual photovoltaic modules 4 in the same orientation after installation of the drive means 20, should also be highlighted. These three aspects, namely the fixing apparatus having the possibility of manually setting the horizontal inclination, the friction braking device and the adjusting device are in principle also realizable independently of one another. The fixing apparatus and the adjusting device can therefore also be realized independently of the configuration with the friction braking device. We reserve the right to file partial applications relating to these aspects independently of the configuration with the friction braking device.

The following is a concise list of reference signs used in the above description of the invention:
2 Supporting framework
4 Photovoltaic module
6 Supporting column, supporting mast
8 Supporting frame
10 Horizontal pivot axis
12 Strut
14 Linkage
16 Perforated plate
17 Fastening foot
18 Driver element
20 Drive means, drive device
22 Drive
24 Guide slot
26 Lateral surface, jacket surface
28 Guide element
30 Guide region
34 Supporting tube
36A,B Part region
38A,B Fastening flange
40 Lug

1. A supporting framework for a photovoltaic module for tracking a movement of the sun, the supporting framework comprising:
a supporting column and a driver element surrounding said supporting column and connected thereto so as to rotate therewith;
a drive device for transmitting a drive force to said driver element disposed to wrap around said driver element in an assembled state;
a friction braking device disposed to avoid slip between said driver element and said drive device;
said driver element having a lateral surface formed with at least one guide slot extending in a circumferential direction, with said drive device resting in said guide slot in the assembled state such that said drive device extends in a straight line along a length of said guide slot and rests against edges at an inlet-side end and an outlet-side end of said guide slot.

2. The supporting framework according to claim 1, which comprises a guide element disposed on said driver element for guiding said drive device.

3. The supporting framework according to claim 2, wherein said guide element forms a guide region converging toward said friction braking device.

4. The supporting framework according to claim 1, which comprises a supporting frame on which the photovoltaic module rests in the assembled state, and a fixing apparatus for manually setting a horizontal inclination angle of said supporting frame and the photovoltaic module.

5. The supporting framework according to claim 4, wherein said fixing apparatus is configured with a plurality of discrete locking positions in order to set defined horizontal inclination angles.

6. The supporting framework according to claim 5, wherein said fixing apparatus comprises a linkage with one side connected to said supporting column and another side connected to said supporting frame, wherein a variable fastening end of said linkage is lockable in a plurality of different positions in order to set the horizontal inclination angle.

7. The supporting framework according to claim 6, wherein said fixing apparatus includes a perforated plate fastened to said supporting column, and said variable fastening end is lockable in mutually different positions to said perforated plate.

8. The supporting framework according to claim 1, which comprises a fastening foot configured to fasten the supporting framework to the ground, and an adjusting device for a rotary adjustment of partial regions of said supporting column with respect to one another.

9. A tracking device for a photovoltaic system having a plurality of supporting frameworks each according to claim 1, the tracking device comprising: a common drive and a common drive device for transmitting an actuating movement for vertical tracking to the individual said supporting frameworks, wherein said drive device is guided around said driver elements.
